(19) United States
(12) Patent Application Publication
(10) Pub. No.: US 2024/0177991 A1
(43) Pub. Date: May 30, 2024

(54) METHOD OF MANUFACTURING SEMICONDUCTOR DEVICE, GAS SUPPLY METHOD, SUBSTRATE PROCESSING APPARATUS AND NON-TRANSITORY COMPUTER-READABLE RECORDING MEDIUM

(71) Applicant: Kokusai Electric Corporation, Tokyo (JP)

(72) Inventors: Yukinori ABURATANI, Toyama-shi (JP); Yoshitomo HASHIMOTO, Toyama-shi (JP); Kimihiko NAKATANI, Toyama-shi (JP)

(73) Assignee: Kokusai Electric Corporation, Tokyo (JP)

(21) Appl. No.: 18/437,565

(22) Filed: Feb. 9, 2024

Related U.S. Application Data
(63) Continuation of application No. PCT/JP21/34540, filed on Sep. 21, 2021.

(51) Int. Cl. H01L 21/02; H01L 21/67

(52) U.S. Cl. CPC H01L 21/02337; H01L 21/0212; H01L 21/67017

(57) ABSTRACT

It is possible to suppress a metal contamination of a substrate due to a corrosion of a piping. There is provided a technique that includes: (a) vaporizing a source material stored in a tank by introducing an inert gas through a primary piping of the tank, and supplying a vaporized gas generated by vaporizing the source material into a process chamber through a secondary piping of the tank; and (b) supplying an oxygen-containing gas to the secondary piping through which the vaporized gas has passed via a bypass line connecting the primary piping and the secondary piping such that the oxygen-containing gas is supplied without passing through the tank.

### CROSS-REFERENCE TO RELATED PATENT APPLICATION

This application is a bypass continuation application of PCT International Application No. PCT/JP2021/034540, filed on Sep. 21, 2021, in the WIPO, the entire contents of which are hereby incorporated by reference.

### BACKGROUND

### 1. Field

The present disclosure relates to a method of manufacturing semiconductor device, a gas supply method, a substrate processing apparatus and a non-transitory computer-readable recording medium.

### 2. Related Art

According to some related arts, as a step of a manufacturing process of a semiconductor device, a process of forming a film on a substrate may be performed. A gas used for forming the film on the substrate (for example, pure water (steam) with few impurities) may corrode a stainless steel piping on which a passive film is formed.

### SUMMARY

According to the present disclosure, there is provided a technique capable of suppressing a metal contamination of a substrate due to a corrosion of a piping.

According to an aspect of the present disclosure, there is provided a technique that includes: (a) vaporizing a source material stored in a tank by introducing an inert gas through a primary piping of the tank, and supplying a vaporized gas generated by vaporizing the source material into a process chamber through a secondary piping of the tank; and (b) supplying an oxygen-containing gas to the secondary piping through which the vaporized gas has passed via a bypass line connecting the primary piping and the secondary piping such that the oxygen-containing gas is supplied without passing through the tank.

### BRIEF DESCRIPTION OF THE DRAWINGS

FIG. 1 is a diagram schematically illustrating a vertical cross-section of a vertical type process furnace of a substrate processing apparatus according to a first embodiment of the present disclosure.

FIG. 2 is a diagram schematically illustrating a horizontal cross-section, taken along a line A-A shown in FIG. 1, of the vertical type process furnace of the substrate processing apparatus according to the first embodiment of the present disclosure.

FIG. 3 is a diagram schematically illustrating a tank of a gas supply assembly and its periphery of the substrate processing apparatus according to the first embodiment of the present disclosure.

FIG. 4 is a block diagram schematically illustrating a configuration of a controller and related components of the substrate processing apparatus according to the first embodiment of the present disclosure.

FIG. 5 is a diagram schematically illustrating a substrate processing sequence according to the first embodiment of the present disclosure.

FIG. 6 is a diagram schematically illustrating operations around the tank when a reactive gas is supplied in accordance with the substrate processing sequence according to the first embodiment of the present disclosure.

FIGS. 7A and 7B are diagrams schematically illustrating operations around the tank when a piping purge is performed according to the first embodiment of the present disclosure.

FIG. 8 is a diagram schematically illustrating operations around the tank when a piping purge is performed according to a second embodiment of the present disclosure.

FIG. 9A is a diagram schematically illustrating operations around the tank when a piping purge is performed according to a third embodiment of the present disclosure, and

FIG. 9B is a diagram schematically illustrating operations around the tank when a piping purge is performed according to a fourth embodiment of the present disclosure.

### DETAILED DESCRIPTION

Hereinafter, embodiments of the technique of the present disclosure will be described in detail with reference to the drawings.

### First Embodiment of Present Disclosure

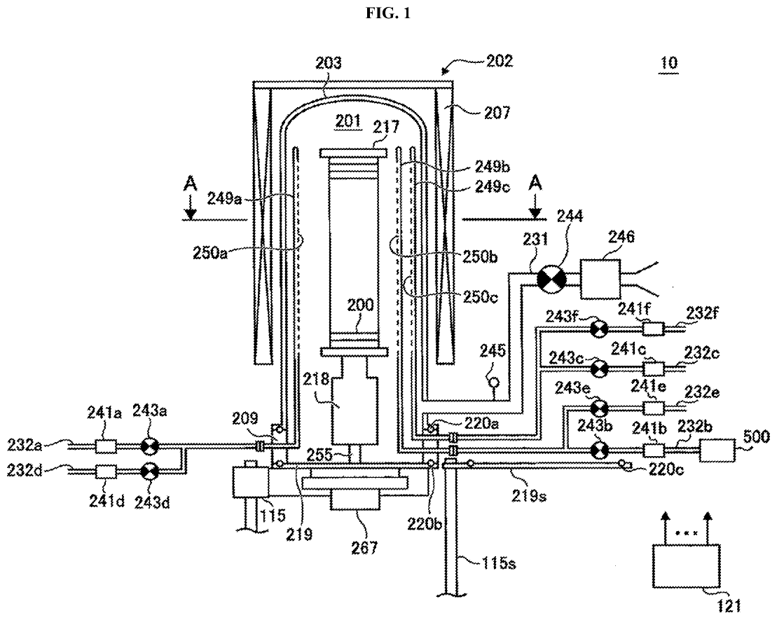

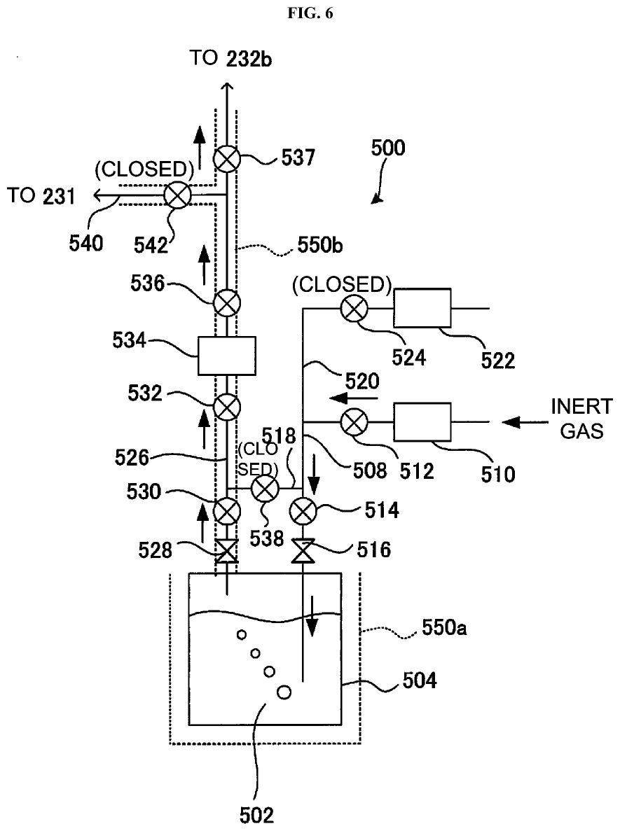

Hereinafter, a first embodiment of the technique of the present disclosure will be described in detail mainly with reference to FIGS. 1 to 6 and FIGS. 7A and 7B. For example, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

As shown in FIG. 1, a substrate processing apparatus 10 according to the present embodiment includes a vertical type process furnace (also simply referred to as a “process furnace”) 202. The process furnace 202 includes a heater 207 serving as a heating structure (which is a heating apparatus). The heater 207 is of a cylindrical shape, and is vertically installed while being supported by a heater base (not shown) serving as a support plate. The heater 207 also functions as an activator (also referred to as an “exciter”) capable of activating (or exciting) a gas by a heat as described later.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold (also referred to as an “inlet flange”) 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. The reaction tube 203 is installed vertically while the manifold 209 is being supported by the heater base. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate in a horizontal orientation to be vertically arranged in a multistage manner by a boat 217 described later. Hereinafter, the plurality of wafers including the wafer 200 may also be simply referred to as “wafers 200”.

Nozzles 249a, 249b and 249c are provided in the process chamber 201 so as to penetrate the manifold 209. For example, each of the nozzles 249a, 249b and 249c is made of a heat resistant material such as quartz and silicon carbide (SIC). Gas supply pipes 232a, 232b and 232c are connected to the nozzles 249a, 249b and 249c, respectively. As described above, for example, the three nozzles 249a, 249b and 249c and the three gas supply pipes 232a, 232b and 232c are provided at the process vessel (that is, the manifold 209), and thereby it is possible to supply various gases into the process chamber 201 through the three nozzles 249a, 249b and 249c and the three gas supply pipes 232a, 232b and 232c.

Mass flow controllers (also simply referred to as “MFCs”) 241a, 241b and 241c serving as flow rate controllers (flow rate control structures) and valves 243a, 243b and 243c serving as opening/closing valves are sequentially installed at the gas supply pipes 232a, 232b and 232c, respectively, in this order from upstream sides to downstream sides of the gas supply pipes 232a, 232b and 232c in a gas flow direction. Gas supply pipes 232d, 232e and 232f are connected to the gas supply pipes 232a, 232b and 232c, respectively, at downstream sides of the valve 243a, 243b and 243c of the gas supply pipes 232a, 232b and 232c. An inert gas may be supplied through the gas supply pipes 232d, 232e and 232f. MFCs 241d, 241e and 241f serving as flow rate controllers (flow rate control structures) and valves 243d, 243e and 243f serving as opening/closing valves are sequentially installed at the gas supply pipes 232d, 232e and 232f, respectively, in this order from upstream sides to downstream sides of the gas supply pipes 232d, 232e and 232f in the gas flow direction. For example, each of the gas supply pipes 232a to 232f is made of a metal material such as SUS. A gas supply assembly 500 to be described in detail later is connected to a base end of the gas supply pipe 232b.

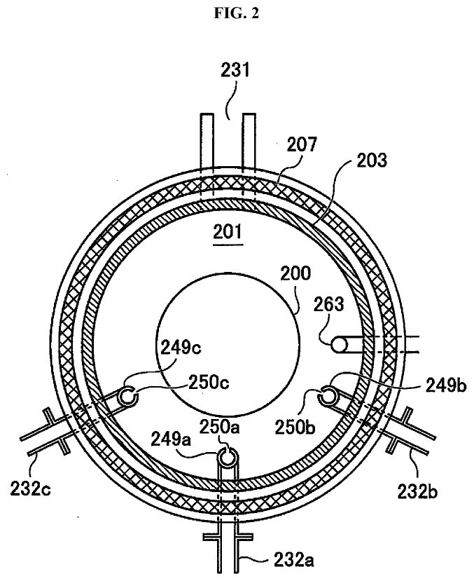

The nozzles 249a to 249c are connected to a front ends (tips) of the gas supply pipes 232a to 232c, respectively. As shown in FIG. 2, each of the nozzles 249a to 249c is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along a stacking direction of the wafers 200). That is, each of the nozzles 249a to 249c is installed in a region that is located beside and horizontally surrounds a wafer arrangement region in which the wafers 200 are arranged (stacked) along the wafer arrangement region. That is, the nozzles 249a to 249c are provided beside edges (peripheries) of the wafers 200 loaded (transferred) into the process chamber 201, and are provided perpendicular to surfaces (flat surfaces) of the wafers 200. Each of the nozzles 249a to 249c may be configured as an L-shaped long nozzle. Horizontal portions of the nozzles 249a to 249c are installed so as to penetrate a side wall of the manifold 209. Vertical portions of the nozzles 249a to 249c are installed so as to extend upward at least from a lower end toward an upper end of the wafer arrangement direction. A plurality of gas supply holes 250a, a plurality of gas supply holes 250b and a plurality of gas supply holes 250c are provided at side surfaces of the nozzles 249a, 249b and 249c, respectively. Gases can be supplied via the gas supply holes 250a, the gas supply holes 250b and the gas supply holes 250c, respectively. The gas supply holes 250a, the gas supply holes 250b and the gas supply holes 250c are open toward a center of the reaction tube 203, and are configured such that the gases are supplied toward the wafers 200 via the gas supply holes 250a, the gas supply holes 250b and the gas supply holes 250c, respectively. The gas supply holes 250a, the gas supply holes 250b and the gas supply holes 250c are provided from the lower portion toward the upper portion of the reaction tube 203. An opening area of each of the gas supply holes 250a, the gas supply holes 250b and the gas supply holes 250c is the same, and each of the gas supply holes 250a, the gas supply holes 250b and the gas supply holes 250c are provided at the same pitch.

According to the present embodiment, the gases such as a source gas, a reactive gas and a catalyst gas are respectively supplied through the nozzles 249a to 249c, which are provided in a vertically elongated annular space (that is, a cylindrical space) when viewed from above defined by the inner wall of the reaction tube 203 and the edges (peripheries) of the wafers 200 stacked in the reaction tube 203. Then, the gases are respectively ejected into the reaction tube 203 in the vicinity of the wafers 200 first through the gas supply holes 250a of the nozzle 249a, the gas supply holes 250b of the nozzle 249b and the gas supply holes 250c of the nozzle 249c. Each of the gases ejected into the reaction tube 203 mainly flows parallel to the surfaces of the wafers 200, that is, in a horizontal direction. Thereby, it is possible to uniformly supply the gases to each of the wafers 200, and it is also possible to improve a thickness uniformity of a film formed on each of the wafers 200. After flowing over the surfaces of the wafers 200, the gas (for example, a residual gas remaining after the reaction) flows toward an exhaust port, that is, toward an exhaust pipe 231 described later. However, a flow direction of the residual gas may be determined appropriately depending on a location of the exhaust port, and is not limited to a vertical direction.

For example, the source gas containing a predetermined element is supplied into the process chamber 201 through the gas supply pipe 232a provided with the MFC 241a and the valve 243a and the nozzle 249a.

For example, the reactive gas (reactant) whose chemical structure is different from that of the source gas is supplied into the process chamber 201 through the gas supply assembly 500, the gas supply pipe 232b provided with the MFC 241b and the valve 243b and the nozzle 249b.

The catalyst gas capable of promoting a film-forming reaction by the source gas and the reactive gas described above is supplied into the process chamber 201 through the gas supply pipe 232c provided with the MFC 241c and the valve 243c and the nozzle 249c.

For example, a part of a molecular structure of a catalyst (that is, the catalyst gas), which will be exemplified in the present specification, may decompose during a film-forming process described later. Strictly speaking, a substance whose molecular structure partially changes before and after a chemical reaction is not a “catalyst”. However, in the present specification, even when a part of the substance decomposes in a course of the chemical reaction, if majority of the substance does not decompose and is capable of changing a reaction rate such that the substance substantially acts as a catalyst, such a substance may also be referred to as a “catalyst”.

For example, the inert gas such as nitrogen (N₂) gas is supplied into the process chamber 201 through the gas supply pipes 232d to 232f provided with the MFCs 241d to 241f and the valves 243d to 243f, respectively, the gas supply pipes 232a to 232c and the nozzles 249a to 249c.

When the source gas described above is supplied through the gas supply pipe 232a, a source gas supplier (which is a source gas supply structure or a source gas supply system) is constituted mainly by the gas supply pipe 232a, the MFC 241a and the valve 243a. The source gas supplier may further include the nozzle 249a. The source gas supplier may also be referred to as a “source supplier” which is a source supply structure or a source supply system.

When the reactive gas described above is supplied through the gas supply pipe 232b, a reactive gas supplier (which is a reactive gas supply structure or a reactive gas supply system) is constituted mainly by the gas supply pipe 232b, the MFC 241b and the valve 243b. The reactive gas supplier may further include the nozzle 249b and the gas supply assembly 500. The reactive gas supplier may also be referred to as a “reactant supplier” which is a reactant supply structure or a reactant supply system.

When the catalyst gas described above is supplied through the gas supply pipe 232c, a catalyst gas supplier (which is a catalyst gas supply structure or a catalyst gas supply system) is constituted mainly by the gas supply pipe 232c, the MFC 241c and the valve 243c. The catalyst gas supplier may further include the nozzle 249c. The catalyst gas supplier may also be referred to as a “catalyst supplier” which is a catalyst supply structure or a catalyst supply system.

Further, an inert gas supplier (which is an inert gas supply structure or an inert gas supply system) is constituted mainly by the gas supply pipes 232d to 232f, the MFCs 241d to 241f and the valves 243d to 243f.

For example, the exhaust pipe 231 through which an inner atmosphere (inner atmosphere) of the process chamber 201 is exhausted is provided at the reaction tube 203. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (which is a pressure detection structure) to detect a pressure (inner pressure) of the process chamber 201, and the APC valve 244 serves as a pressure regulator (pressure adjusting structure). With the vacuum pump 246 in operation, the APC valve 244 may be opened or closed to perform a vacuum exhaust of the process chamber 201 or stop the vacuum exhaust. Further, with the vacuum pump 246 in operation, an opening degree of the APC valve 244 may be adjusted based on pressure information detected by the pressure sensor 245, in order to control (or adjust) the inner pressure of the process chamber 201. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing (or closing) a lower end opening of the manifold 209 is provided under the manifold 209. The seal cap 219 is configured to be in contact with the lower end of the manifold 209 from thereunder. For example, the seal cap 219 is made of a metal material such as SUS, and is of a disk shape. An O-ring 220b serving as a seal is provided on an upper surface of the seal cap 219 so as to be in contact with the lower end of the manifold 209. A rotator 267 configured to rotate the boat 217 described later is provided under the seal cap 219 in a manner opposite to the process chamber 201. For example, a rotating shaft 255 of the rotator 267 is connected to the boat 217 through the seal cap 219. As the rotator 267 rotates the boat 217, the wafers 200 accommodated in the boat 217 are rotated. The seal cap 219 is elevated or lowered in the vertical direction by a boat elevator 115 serving as an elevating structure provided outside the reaction tube 203. The boat elevator 115 is configured to be capable of transferring (loading) the boat 217 into the process chamber 201 and capable of transferring (unloading) the boat 217 out of the process chamber 201 by elevating and lowering the seal cap 219. The boat elevator 115 serves as a transfer device (which is a transfer structure or a transfer system) capable of loading the boat 217 and the wafers 200 accommodated therein into the process chamber 201 and capable of unloading the boat 217 and the wafers 200 accommodated therein out of the process chamber 201. A shutter 219s serving as a furnace opening lid capable of airtightly sealing (or closing) the lower end opening of the manifold 209 is provided under the manifold 209. The shutter 219s is configured to be capable of airtightly sealing (closing) the lower end opening of the manifold 209 when the seal cap 219 is lowered by the boat elevator 115. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The boat 217 (which is a substrate support or a substrate retainer) is configured to accommodate (or support) the wafers 200 (for example, 25 to 200 wafers) along the vertical direction while the wafers 200 are horizontally oriented with their centers aligned with one another with a predetermined interval therebetween in a multistage manner. For example, the boat 217 is made of a heat resistant material such as quartz and SiC. A heat insulating cylinder 218 is provided under the boat 217. For example, the heat insulating cylinder 218 is made of a heat resistant material such as quartz and SiC. With such a configuration, the heat insulating cylinder 218 suppresses a transmission of the heat from the heater 207 to the seal cap 219. However, the present embodiment is not limited thereto. For example, instead of the heat insulating cylinder 218, a plurality of heat insulating plates (not shown) made of a heat resistant material such as quartz and SiC may be provided in a multistage manner under the boat 217.

A temperature sensor 263 serving as a temperature detector is installed in the reaction tube 203. A state of electric conduction to the heater 207 is adjusted based on temperature information detected by the temperature sensor 263 such that a desired temperature distribution of a temperature (inner temperature) of the process chamber 201 can be obtained. Similar to the nozzles 249a to 249c, the temperature sensor 263 is L-shaped, and is provided along the inner wall of the reaction tube 203.

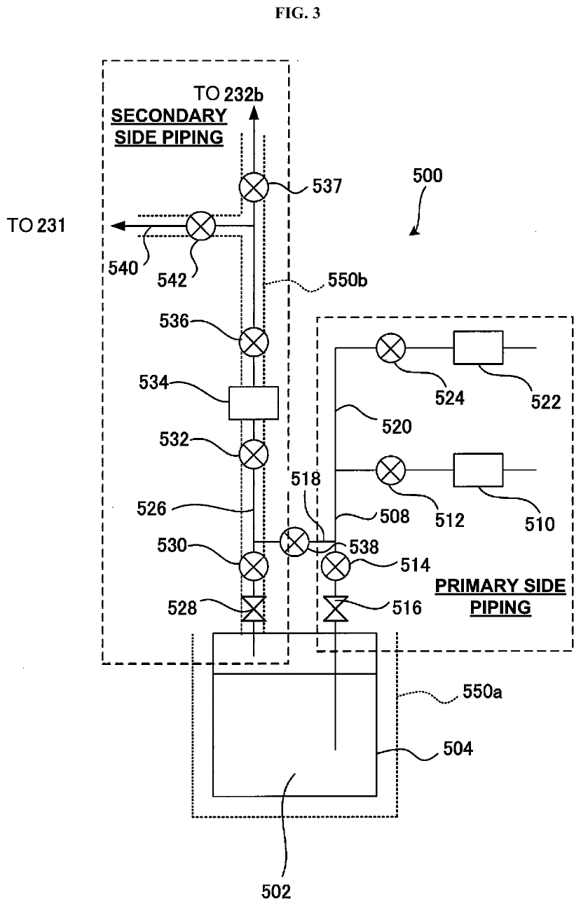

Subsequently, the gas supply assembly 500 through which the reactive gas is supplied into the gas supply pipe 232b will be described with reference to FIG. 3. In the gas supply assembly 500, a liquid source material 502 stored in a tank 504 is vaporized by a sub-heater 550a described later. It is possible to pump the gas vaporized by the sub-heater 550a (hereinafter, also simply referred to as a “vaporized gas”) by increasing an inner pressure of the tank 504 with a carrier gas. The vaporized gas generated by vaporizing the liquid source material 502 is pushed out by the carrier gas, and the vaporized gas is supplied together with the carrier gas as the reactive gas into the gas supply pipe 232b.

The tank 504 containing the liquid source material 502 is connected to the gas supply pipe 232b via a gas supply pipe 526.

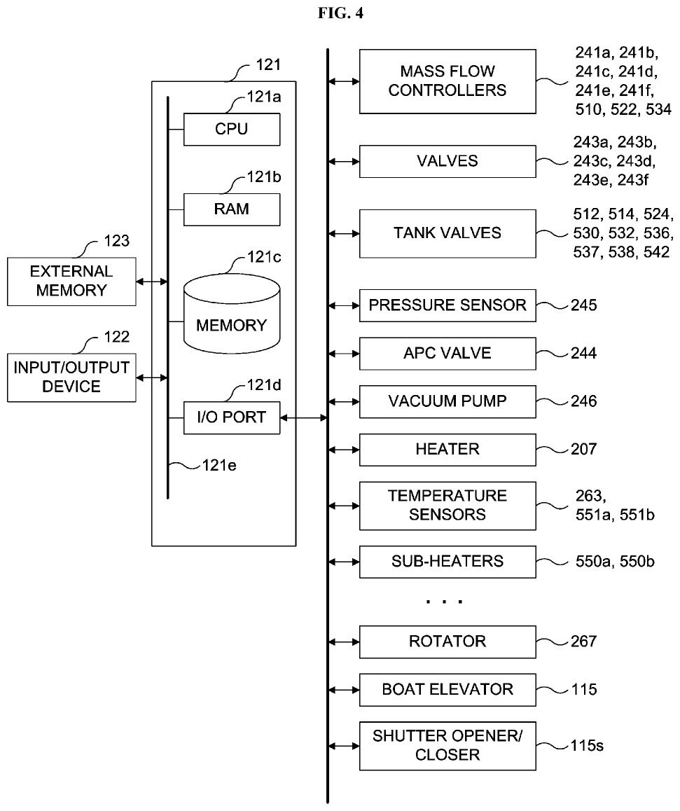

The tank 504 is a container capable of containing (storing) the liquid source material 502, and is configured as a vaporizer (also referred to as a “bubbler”) configured to vaporize the liquid source material 502 by bubbling with the carrier gas to generate the vaporized gas. The sub-heater 550a is provided around the tank 504 to heat the tank 504 and the liquid source material 502 in the tank 504. Further, a temperature sensor 551a (see FIG. 4) is provided inside the tank 504 to detect an inner temperature of the tank 504. Further, a gas supply pipe 508 is connected to the tank 504 to supply the inert gas serving as the carrier gas into the tank 504.

For example, a mass flow controller (MFC) 510 serving as a flow rate controller (flow rate control structure), tank valves 512 and 514 serving as opening/closing valves and a hand valve 516 serving as an opening/closing valve configured to be opened or closed manually are sequentially installed at the gas supply pipe 508 in this order from an upstream side to a downstream side of the gas supply pipe 508 in the gas flow direction.

A gas supply pipe 520 through which an oxygen-containing gas serving as a piping purge gas for purging mainly the gas supply pipe is supplied is connected to the gas supply pipe 508 at a downstream side of the tank valve 512 of the gas supply pipe 508 and at an upstream side of a connection portion with a connection pipe 518 described later.

For example, a mass flow controller (MFC) 522 serving as a flow rate controller (flow rate control structure) and a tank valve 5244 serving as an opening/closing valve are sequentially installed at the gas supply pipe 520 in this order from an upstream side to a downstream side of the gas supply pipe 520 in the gas flow direction.

The gas supply pipe 508 and the gas supply pipe 520 are used as a “primary piping” of the tank 504. In the present embodiment, the primary piping refers to a piping on a portion (in the gas supply assembly 500) through which the gas is supplied into the tank 504.

The gas supply pipe 526 connected to the gas supply pipe 232b is connected to the tank 504. The vaporized gas vaporized in the tank 504 is supplied to the gas supply pipe 232b as the reactive gas through the gas supply pipe 526.

For example, a hand valve 528 serving as an opening/closing valve configured to be opened or closed manually, tank valves 530 and 532 serving as opening/closing valves, a mass flow controller (MFC) 534 serving as a flow rate controller (flow rate control structure) and tank valves 536 and 537 serving as opening/closing valves are sequentially installed at the gas supply pipe 526 in this order from an upstream side to a downstream side of the gas supply pipe 526 in the gas flow direction. That is, the tank valves 530, 532, 536, and 537 are provided at the gas supply pipe 526.

For example, a connection pipe 540 serving as a vent line is connected to the gas supply pipe 526 between the tank valve 536 and the tank valve 537. The connection pipe 540 is connected to the gas supply pipe 526 at a downstream side of the APC valve 244 of the exhaust pipe 231 without passing through the process chamber 201. A tank valve 542 serving as an opening/closing valve is provided at the connection pipe 540.

The gas supply pipe 526 is used as a “secondary piping” of the tank 504. In the present embodiment, the secondary piping refers to the entire part of piping on a portion (in the gas supply assembly 500) through which the gas output from the tank 504 flows. For example, the secondary piping refers to the piping through which the gas vaporized from the liquid source material 502 in the tank 504 is supplied to the process chamber 201 via the gas supply pipe 232b. For example, the secondary piping may further include a piping through which the gas output from the tank 504 is supplied to the exhaust pipe 231 such that the gas is supplied without passing through the gas supply pipe 232b. In such a case, the secondary piping may further include the connection pipe 540. A sub-heater 550b is provided around the gas supply pipe 526 and the connection pipe 540 to heat the gas supply pipe 526, the connection pipe 540 and the vaporized gas in the gas supply pipe 526 and the connection pipe 540. Further, a temperature sensor 551b (see FIG. 4) is provided adjacent to the gas supply pipe 526 and the connection pipe 540 to detect a temperature of each of the gas supply pipe 526 and the connection pipe 540.

The connection pipe 518 serving as a bypass line configured to connect the gas supply pipe 508 and the gas supply pipe 526 is connected between the tank valve 514 and the connection portion of the gas supply pipe 508 with the gas supply pipe 520 and between the tank valve 530 and the tank valve 532 of the gas supply pipe 526. In the present embodiment, the “bypass line” refers to a piping capable of supplying the gas from the primary side piping of the tank 504 to the secondary side piping of the tank 504 such that the gas is supplied without passing through the tank 504. A tank valve 538 serving as an opening/closing valve is provided at the connection pipe 518.

When the reactive gas described above is supplied through the gas supply pipe 232b, a process gas supplier (which is a process gas supply structure or a process gas supply system) through which the liquid source material 502 of the reactive gas is vaporized and supplied is constituted mainly by the gas supply pipe 508, the MFC 510, the tank valves 512 and 514, the hand valve 516, the tank 504, the gas supply pipe 526, the hand valve 528, the tank valves 530 and 532, the MFC 534 and the tank valves 536 and 537. Further, the reactive gas supplier described above may further include the process gas supplier.

That is, the process gas supplier is configured to be capable of introducing the inert gas serving as the carrier gas through the gas supply pipe 508 of the primary piping of the tank 504 by opening the tank valves 512 and 514 and the hand valve 516, capable of bubbling and vaporizing the liquid source material 502 stored in the tank 504 by the inert gas introduced thereto, and capable of supplying the vaporized gas (which is generated by vaporizing the liquid source material 502 stored in the tank 504) and the inert gas to the gas supply pipe 232b as the reactive gas through the secondary piping of the tank 504.

Further, when the oxygen-containing gas described above is supplied through the gas supply pipe 520 and exhausted through the secondary piping of the tank 504, a purge gas supplier (which is a purge gas supply structure or a purge gas supply system) for purging the gas supply pipe is constituted mainly by the gas supply pipe 520, the MFC 522, the tank valve 524, the gas supply pipe 508, the connection pipe 518, the tank valve 538, the gas supply pipe 526, the tank valve 532, the MFC 534, the tank valve 536, the connection pipe 540 and the tank valve 542. Further, in such a case, the purge gas supplier may also be referred to as an “oxygen-containing gas supplier” which is an oxygen-containing gas supply structure or an oxygen-containing gas supply system.

For example, by opening the tank valves 524 and 538, the purge gas supplier is configured to be capable of flowing (supplying) the piping purge gas supplied through the gas supply pipe 520 to the secondary piping through which the vaporized gas has passed. More specifically, the purge gas supplier is configured to be capable of supplying the piping purge gas through the bypass line connecting the primary piping and the secondary piping such that the piping purge gas is supplied without passing through the tank 504.

It is preferable that a coating film of a fluorine-based resin is provided (formed) on an inner portion of a piping between a portion (of the gas supply pipe 526) connected to the tank 504 and the tank valve 530 (which is installed closest to the tank 504 among the tank valves of the secondary piping). In a manner described above, by coating the inner portion of the piping from the tank 504 to the tank valve 530 (which is particularly prone to a corrosion) with the coating film of the fluorine-based resin, it is possible to suppress the corrosion of the piping. As a result, it is possible to reduce a metal contamination caused by the corrosion of the piping.

For example, the fluorine-based resin refers to at least one resin selected from the group of polytetrafluoroethylene (PTFE), perfluoroalkoxy alkane (PFA), ethylene-tetrafluoroethylene copolymer (ETFE), perfluoroethylene-propene copolymer (FEP), polyvinylidene fluoride (PVDF), polychlorotrifluoroethylene (PCTFE) and ethylene-chlorotrifluoroethylene copolymer (ECTFE).

In addition, the gas supply pipe 526 and the connection pipe 540 (which serve as the secondary piping) are made of a metal material containing at least chromium (Cr), and a passive film (which is an oxide film) is formed on surfaces of the gas supply pipe 526 and the connection pipe 540. Since the passive film is formed on the surface of the piping containing chromium (which is corrosion resistant) in a manner described above, it is possible to suppress the corrosion of the piping. In addition, even when a part of the passive film is broken, by supplying the oxygen-containing gas and reacting the piping with oxygen atoms in the oxygen-containing gas to oxidize the surface of the piping, it is possible to repair (or re-form) the passive film.

As shown in FIG. 4, a controller 121 serving as a control structure (control apparatus) is constituted by a computer including a CPU (Central Processing Unit) 121a, a RAM (Random Access Memory) 121b, a memory 121c and an I/O port (input/output port) 121d. The RAM 121b, the memory 121c and the I/O port 121d may exchange data with the CPU 121a through an internal bus 121e. For example, an input/output device 122 constituted by a component such as a touch panel is connected to the controller 121.

The memory 121c is configured by a component such as a flash memory and a hard disk drive (HDD). For example, a control program configured to control an operation of the substrate processing apparatus 10 and a process recipe containing information on sequences and conditions of a substrate processing described later may be readably stored in the memory 121c. The process recipe is obtained by combining steps of the substrate processing described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the process recipe alone, may refer to the control program alone or may refer to both of the process recipe and the control program. The RAM 121b functions as a memory area (work area) where a program or data read by the CPU 121a is temporarily stored.

The I/O port 121d is connected to the components described above such as the MFCs 241a to 241f, 510, 522 and 534, the valves 243a to 243f, the tank valves 512, 514, 524, 530, 532, 536, 537, 538 and 542, the pressure sensor 245, the APC valve 244, the vacuum pump 246, the heater 207, the temperature sensors 263, 551a and 551b, the sub-heaters 550a and 550b, the rotator 267, the boat elevator 115 and the shutter opener/closer 115s.

The CPU 121a is configured to read the control program from the memory 121c and execute the read control program. In addition, the CPU 121a is configured to read the process recipe from the memory 121c, for example, in accordance with an operation command inputted from the input/output device 122. In accordance with contents of the read process recipe, the CPU 121a may be configured to be capable of controlling various operations such as flow rate adjusting operations for various gases by the MFCs 241a to 241f, 510, 522 and 534, opening and closing operations of the valves 243a to 243f, opening and closing operations of the tank valves 512, 514, 524, 530, 532, 536, 537, 538 and 542, an opening and closing operation of the APC valve 244, a pressure regulating operation (pressure adjusting operation) by the APC valve 244 based on the pressure sensor 245, a start and stop operation of the vacuum pump 246, a temperature regulating operation (temperature adjusting operation) by the heater 207 based on the temperature sensor 263, temperature regulating operations (temperature adjusting operations) by the sub-heaters 550a and 550b based on the temperature sensors 551a and 551b, an operation of adjusting a rotation and a rotation speed of the boat 217 by the rotator 267, an elevating and lowering operation of the boat 217 by the boat elevator 115, and an opening and closing operation of the shutter 219s by the shutter opener/closer 115s.

The controller 121 may be embodied by installing the above-described program stored in an external memory 123 into the computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication structure such as the Internet and a dedicated line may be used for providing the program to the computer.

### (2) Substrate Processing

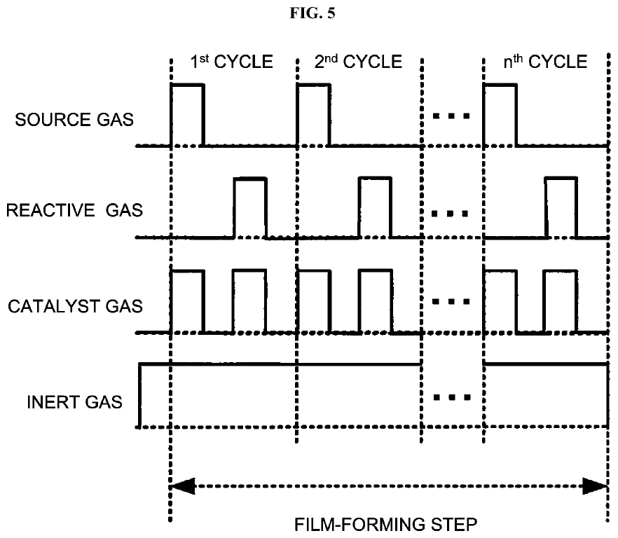

Hereinafter, an example of a process sequence (that is, a film-forming sequence) of the substrate processing of forming a film on the wafer 200 serving as the substrate by using the substrate processing apparatus 10 described above, which is a part of a manufacturing process of a semiconductor device, will be described with reference to FIG. 5. In the following descriptions, operations of components constituting the substrate processing apparatus 10 are controlled by the controller 121.

In the substrate processing shown in FIG. 5, the film is formed on the wafer 200 by performing a cycle a predetermined number of times (at least once). The cycle may include a step of supplying the source gas and the catalyst gas to the wafer 200 and a step of supplying the reactive gas and the catalyst gas to the wafer 200. In the cycle, the step of supplying the source gas and the catalyst gas and the step of supplying the reactive gas and the catalyst gas are performed non-simultaneously, that is, alternately without synchronization.

In the present specification, the term “wafer” may refer to “a wafer itself”, or may refer to “a wafer and a stacked structure (aggregated structure) of a predetermined layer (or layers) or a film (or films) formed on a surface of the wafer”. That is, the term “wafer” may collectively refer to “a wafer and layers or films formed on a surface of the wafer”. In the present specification, the term “a surface of a wafer” may refer to “a surface (exposed surface) of a wafer itself”, or may refer to “a surface of a predetermined layer or a film formed on a wafer, i.e. a top surface (uppermost surface) of the wafer as a stacked structure”.

Thus, in the present specification, “supplying a predetermined gas to a wafer” may refer to “directly supplying a predetermined gas to a surface (exposed surface) of a wafer itself”, or may refer to “supplying a predetermined gas to a layer or a film formed on a wafer”, that is, “supplying a predetermined gas to a top surface (uppermost surface) of a wafer as a stacked structure”. In addition, in the present specification, “forming a predetermined layer (or film) on a wafer” may refer to “forming a predetermined layer (or film) directly on a surface (exposed surface) of a wafer itself” or may refer to “forming a predetermined layer (or film) on a layer (or film) formed on a wafer, i.e. a top surface (uppermost surface) of the wafer as a stacked structure”.

In the present specification, the terms “substrate” and “wafer” may be used as substantially the same meaning.

### Wafer Charging Step and Boat Loading Step

The wafers 200 are charged (transferred) into the boat 217 (wafer charging step). Thereafter, the shutter 219s is moved by the shutter opener/closer 115s to open the lower end opening of the manifold 209 (shutter opening step). Thereafter, as shown in FIG. 1, the boat 217 supporting (accommodating) the wafers 200 is elevated by the boat elevator 115 and loaded (transferred) into the process chamber 201 (boat loading step). With the boat 217 loaded, the seal cap 219 airtightly seals (or closes) the lower end of the manifold 209 via the O-ring 220b.

### Pressure Adjusting Step and Temperature Adjusting Step

Then, the vacuum pump 246 vacuum-exhausts (decompresses and exhausts) the inner atmosphere of the process chamber 201 (that is, a space in which the wafers 200 are present (accommodated)) such that the inner pressure of the process chamber 201 reaches and is maintained at a desired pressure (vacuum degree). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245. The vacuum pump 246 continuously vacuum-exhausts the inner atmosphere of the process chamber 201 until at least a processing of the wafer 200 is completed. In addition, the heater 207 heats the process chamber 201 such that a temperature of the wafer 200 in the process chamber 201 reaches and is maintained at a desired process temperature. When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained. The heater 207 continuously heats the wafer 200 in the process chamber 201 until at least the processing of the wafer 200 is completed. In addition, a rotation of the boat 217 and the wafer 200 is started by the rotator 267. The rotator 267 continuously rotates the boat 217 and the wafer 200 until at least the processing of the wafer 200 is completed.

### Film-Forming Step

Thereafter, a film-forming step is performed by sequentially performing two steps described below, that is, a first step and a second step.

### First Step

In the first step, the source gas and the catalyst gas are supplied onto the wafer 200 in the process chamber 201.

In the present step, the valves 243a and 243c are opened to supply the source gas and the catalyst gas into the gas supply pipes 232a and 232c, respectively. After a flow rate of the source gas is adjusted by the MFC 241a and a flow rate of the catalyst gas is adjusted by the MFC 241c, the source gas whose flow rate is adjusted and the catalyst gas whose flow rate is adjusted are supplied into the process chamber 201 through the nozzles 249a and 249c, respectively. Then, the source gas and the catalyst gas are mixed (post-mixed) after supplied into the process chamber 201, and are exhausted through the exhaust pipe 231. Simultaneously with a supply of the source gas and a supply of the catalyst gas, the valves 243d and 243f are opened to supply the inert gas such as N₂ gas into the gas supply pipes 232d and 232f. After a flow rate of the inert gas is respectively adjusted by the MFCs 241d and 241f, the inert gas whose flow rate is adjusted is supplied into the process chamber 201 together with the source gas and the catalyst gas, and is exhausted through the exhaust pipe 231. In order to prevent the source gas and the catalyst gas from entering the nozzle 249b, the valve 243e is opened to supply the inert gas into the gas supply pipe 232e. The inert gas supplied into the gas supply pipe 232e is supplied into the process chamber 201 through the gas supply pipe 232b and the nozzle 249b, and is exhausted through the exhaust pipe 231.

After a first layer is formed in the present step, the valves 243a and 243c are closed to stop the supply of the source gas and the supply of the catalyst gas into the process chamber 201, respectively. In such a case, with the APC valve 244 open, the vacuum pump 246 vacuum-exhausts the inner atmosphere of the process chamber 201 to remove a substance such as a residual gas remaining in the process chamber 201 (for example, the source gas and the catalyst gas which did not react or which contributed to a formation of the first layer) and reaction by-products from the process chamber 201. In addition, by maintaining the valves 243d to 243f open, the inert gas is continuously supplied into the process chamber 201. The inert gas serves as the purge gas, which improves an efficiency of removing the substance such as the residual gas remaining in the process chamber 201 (for example, the source gas and the catalyst gas which did not react or which contributed to the formation of the first layer) and the reaction by-products from the process chamber 201.

In the present step, the gas remaining in the process chamber 201 may not be completely discharged (or exhausted) or the process chamber 201 may not be completely purged. Even when a small amount of the gas remains in the process chamber 201, the small amount of the gas remaining in the process chamber 201 does not adversely affect a subsequent step (that is, the second step). Therefore, in the present step, the inert gas may not be supplied into the process chamber 201 at a large flow rate. For example, a purge operation of purging the process chamber 201 may be performed by supplying the inert gas of an amount substantially equal to a volume of the reaction tube 203 (or the process chamber 201) such that the second step will not be adversely affected. By not completely purging the process chamber 201 in a manner described above, it is possible to shorten a purge time for purging the process chamber 201, and to improve a throughput. It is also possible to reduce a consumption of the inert gas to the minimum.

As the source gas, for example, a silicon (Si)-containing gas such as bis (trichlorosilyl) methane ((SiCl₃)₂CH₂, abbreviated as BTCSM) gas, ethylenebis (trichlorosilane) gas, that is, 1,2-bis (trichlorosilyl) ethane ((SiCl₃)₂C₂H₄, abbreviated as BTCSE) gas, 1,1,2,2-tetrachloro-1,2-dimethyldisilane ((CH₃)₂Si₂Cl₄, abbreviated as TCDMDS) gas, 1,2-dichloro-1,1,2,2-tetramethyldisilane ((CH₃)₄Si₂Cl₂, abbreviated as DCTMDS) gas, 1-monochloro-1,1,2,2,2-pentamethyldisilane ((CH₃)₅Si₂Cl, abbreviated as MCPMDS) gas, hexachlorodisilane (Si₂Cl₆, abbreviated as HCDS) gas and octachlorotrisilane (Si₃Cl₈, abbreviated as OCTS) gas may be used.

As the catalyst gas, for example, a cyclic amine-based gas such as pyridine (C₅H₅N) gas, aminopyridine (C₅H₆N₂) gas, picoline (C₆H₇N) gas, lutidine (C₇H₉N) gas, piperazine (C₄H₁₀N₂) gas, and piperidine (C₅H₁₁N) gas may be used. Further, as the catalyst gas, for example, a chain amine-based gas such as triethylamine ((C₂H₅)₃N, abbreviated as TEA) gas, diethylamine ((C₂H₅)₂NH, abbreviated as DEA) gas, monoethylamine ((C₂H₅)NH₂, abbreviated as MEA) gas, trimethylamine ((CH₃)₃N, abbreviated as TMA) gas, monomethylamine ((CH₃)NH₂, abbreviated as MMA) gas, or a non-amine-based gas such as ammonia (NH₃) gas may be used.

As the inert gas, for example, instead of or in addition to the N₂ gas, a rare gas such as argon (Ar) gas, helium (He) gas, neon (Ne) gas and xenon (Xe) gas may be used.

### Second Step

In the present step, the reactive gas and the catalyst gas in the present step are supplied onto the wafer 200 in the process chamber 201.

In the present step, the opening and closing operations of the valves 243b, 243c, 243d, 243e and 243f can be controlled in substantially the same manners as those of the valves 243a, 243c, 243d, 243e and 243f in the first step.

In the present step, by opening the tank valves 512 and 514 and the hand valve 516, the inert gas in the present step is supplied into the tank 504 through the gas supply pipe 508. After the flow rate of the inert gas is adjusted by the MFC 510, the inert gas whose flow rate is adjusted is supplied into the tank 504 through the gas supply pipe 508. Thereby, it is possible to promote a vaporization of the liquid source material 502. As a result, the vaporized gas is generated. After a flow rate of the vaporized gas is adjusted by the MFC 534 together with the inert gas, the vaporized gas whose flow rate is adjusted is supplied into the process chamber 201 as the reactive gas through the gas supply pipe 232b.

In the present step, the tank 504 is heated by the sub-heater 550a and the gas supply pipe 526 and the connection pipe 540 are heated by the sub-heater 550b. That is, by using the sub-heaters 550a and 550b, the tank 504 is controlled such that a temperature of the liquid source material 502 is maintained at a boiling temperature or higher, and the gas supply pipe 526 and the connection pipe 540 are controlled such that temperatures (inner temperatures) thereof are maintained at a temperature at which the vaporized gas does not liquefy. Specifically, for example, by adjusting a temperature of the sub-heater 550a based on temperature information detected by the temperature sensor 551a, it is possible to control a temperature (inner temperature) of the tank 504 to be higher than or equal to a vaporization temperature of the liquid source material 502. Further, for example, by adjusting a temperature of the sub-heater 550b based on temperature information detected by the temperature sensor 551b, it is possible to control a temperature (inner temperature) of each of the gas supply pipe 526 and the connection pipe 540 such that the inner temperature of each of the gas supply pipe 526 and the connection pipe 540 is maintained at the temperature at which the vaporized gas does not liquefy. For example, the inner temperature of each of the gas supply pipe 526 and the connection pipe 540 is controlled such that the inner temperature of each of the gas supply pipe 526 and the connection pipe 540 becomes higher as the vaporized gas approaches the gas supply pipe 232b.

Further, in the present step, with the vacuum pump 246 in operation, by adjusting the opening degree of the APC valve 244 based on the pressure information detected by the pressure sensor 245, it is possible to control (or adjust) the inner pressure of the process chamber 201 to a reduced pressure, to control an inner pressure of the primary piping side of the tank 504 and the inner pressure of the tank 504 to a positive pressure, and to control an inner pressure of the secondary piping side of the tank 504 to a reduced pressure.

In a manner described above, by introducing (or supplying) the inert gas through the primary piping of the tank 504, the liquid source material 502 stored in the tank 504 is bubbled and vaporized. That is, by supplying the inert gas into the tank 504 and increasing the inner pressure of the tank 504, the liquid source material 502 is vaporized because the inner pressure of the tank 504 reaches a vapor pressure of the liquid source material 502. Then, the vaporized gas generated by vaporizing the liquid source material 502 and the inert gas are supplied through the secondary piping of the tank 504 into the process chamber 201 as the reactive gas via the gas supply pipe 232b.

After the flow rates of the reactive gas and the catalyst gas are adjusted by the MFCs 241b and 241c, respectively, the reactive gas whose flow rate is adjusted and the catalyst gas whose flow rate is adjusted are supplied into the process chamber 201 through the nozzles 249b and 249c, respectively. Then, the reactive gas and the catalyst gas are mixed (post-mixed) after supplied into the process chamber 201, and are exhausted through the exhaust pipe 231.

By supplying the reactive gas onto the wafer 200, at least a part of the first layer formed on the wafer 200 is oxidized (modified) in the first step. For example, when a H₂O gas is used as the reactive gas, by modifying the first layer, impurities such as chlorine (Cl) contained in the first layer constitute a gaseous substance containing chlorine (for example, a gas containing chlorine and hydrogen (H)) during a modifying reaction using the H₂O gas, and are discharged (exhausted) from the process chamber 201. That is, the impurities such as chlorine in the first layer are separated from the first layer by being extracted or desorbed from the first layer.

The catalyst gas acts as the catalyst capable of weakening a bonding force between atoms of the reactive gas, promoting a decomposition of the reactive gas and promoting a formation of a second layer by a reaction between the reactive gas and the first layer. For example, in a case where the H₂O gas is used as the reactive gas and the pyridine gas is used as the catalyst gas, when the pyridine gas is supplied to the wafer 200, the pyridine gas acts on an oxygen-hydrogen bond (O—H bond) of the H₂O gas, and acts to weaken the bonding force. Hydrogen whose bonding force is weakened reacts with chlorine contained in the first layer formed on the wafer 200 so as to generate a gaseous substance containing chlorine and hydrogen. Further, hydrogen is desorbed from molecules of the H₂O gas, and chlorine is desorbed from the first layer. Oxygen of the H₂O gas whose hydrogen is desorbed bonds with silicon of the first layer in which at least a part of chlorine remains after the chlorine is desorbed. As a result, a layer (that is, the second layer) formed by oxidizing the first layer is formed on the wafer 200.

After the second layer is formed in the present step, the valves 243b and 243c are closed to stop a supply of the reactive gas and a supply of the catalyst gas in the present step into the process chamber 201, respectively. Further, by using substantially the same process procedure as in the first step, a substance such as a residual gas remaining in the process chamber 201 (for example, the reactive gas and the catalyst gas which did not react or which contributed to the formation of the second layer) and reaction by-products from the process chamber 201. In the present step, similar to the first step, the substance such as the gas remaining in the process chamber 201 may not be completely discharged (or exhausted) from the process chamber 201.

As the liquid source material 502, for example, a source material in a liquid state at the normal temperature and the normal pressure or a source material obtained by dissolving a solid source material in a solvent may be used.

As the reactive gas, for example, water vapor (H₂O gas) may be used. In such a case, as the liquid source material 502, for example, pure water (H₂O) may be used. That is, as the reactive gas, a gas such as the H₂O gas obtained by vaporizing the pure water in the gas supply assembly 500 may be used.

As the inert gas in the present step, for example, instead of or in addition to the N₂ gas, the rare gas such as argon (Ar) gas, helium (He) gas, neon (Ne) gas and xenon (Xe) gas may be used.

As the catalyst gas in the present step, the gas exemplified above such as the pyridine gas may be used. That is, as the catalyst gas used in the second step, for example, a gas whose molecular structure (chemical structure) is the same as the catalyst gas used in the first step (that is, a gas whose material is the same as the catalyst gas used in the first step) may be used. Alternatively, as the catalyst gas used in the second step, a gas whose molecular structure (chemical structure) is different from the catalyst gas used in the first step (that is, a gas whose material is different from the catalyst gas used in the first step) may be used.

### Performing Cycle Predetermined Number of Times

By performing the cycle wherein the first step and the second step described above are performed non-simultaneously (that is, alternately without synchronization) at least once (a predetermined number of times), it is possible to form the film of a predetermined composition and a predetermined thickness on the surface of the wafer 200. For example, it is preferable that the cycle described above is repeatedly performed a plurality of times.

### After-Purge Step and Returning to Atmospheric Pressure Step

Then, the N₂ gas is supplied into the process chamber 201 through each of the gas supply pipes 232d to 232f, and is exhausted through the exhaust pipe 231. The N₂ gas acts as the purge gas. Thereby, the inner atmosphere of the process chamber 201 is purged with the purge gas. As a result, the substance such as the residual gas remaining in the process chamber 201 and the reaction by-products remaining in the process chamber 201 can be removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### Boat Unloading Step and Wafer Discharging Step

Thereafter, the seal cap 219 is lowered by the boat elevator 115 and the lower end of the manifold 209 is opened. Then, the boat 217 with the processed wafers 200 supported therein is unloaded (transferred) out of the reaction tube 203 through the lower end of the manifold 209 (boat unloading step). After the boat 217 is unloaded, the shutter 219s is moved such that the lower end opening of the manifold 209 is sealed by the shutter 219s through the O-ring 220c (shutter closing step). After the boat 217 is unloaded out of the reaction tube 203, the processed wafers 200 are discharged (taken out) (transferred) from the boat 217 (wafer discharging step).

### (3) Piping Purge

In a case where the substrate processing is performed by using the gas which is corrosive (that is, a corrosive gas), when the substrate processing described above is repeatedly performed, the secondary piping of the tank 504 configured to supply the corrosive gas is corroded in the gas supply assembly 500. As a result, particles may be generated and the film may be contaminated.

For example, when the gas supply assembly 500 generates the water vapor (H₂O gas) using the pure water (H₂O) as the liquid source material 502 and uses the H₂O gas as the reactive gas, the passive film of the piping through which the H₂O gas flows (is supplied) may be damaged due to an oxygen deficiency. Such a phenomenon is particularly noticeable when the pure water without dissolved oxygen is used. In other words, by supplying the corrosive gas, even stainless steel on which the passive film is formed may be corroded. Further, a component such as iron (Fe), chromium (Cr) and nickel (Ni) generated from the stainless steel (which is corroded) may be introduced (supplied) into the process chamber 201 as the particles. As a result, the substrate to be processed (that is, the wafer 200) may be contaminated.

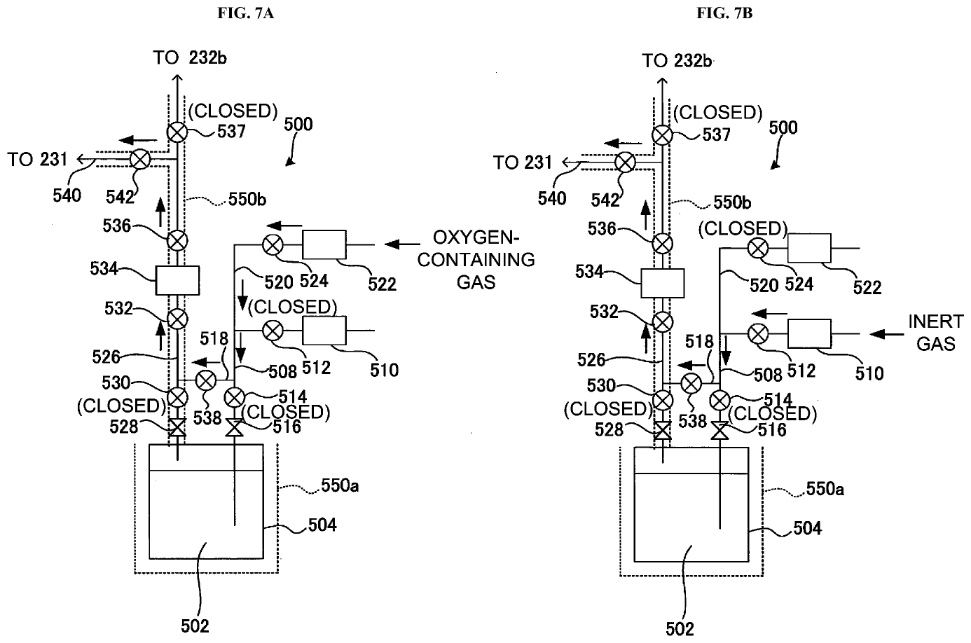

Therefore, while performing the substrate processing as described above, or before or after the substrate processing, the piping purge is performed so as to repair (or re-form) the passive film formed in the secondary piping of the tank 504, which is easily corroded. Hereinafter, an example in which the piping purge is performed while performing the substrate processing described above will be described with reference to FIGS. 7A and 7B. That is, in the present embodiment, in the substrate processing described above (more specifically, in the first step excluding the second step using the gas supply assembly 500), a purge step, an inert gas atmosphere step and an inert gas removal step (which are described below) are performed as the piping purge. That is, the first step and the piping purge are performed simultaneously, and the piping purge and the second step are performed alternately a plurality of times.

### Purge Step

As shown in FIG. 7A, the tank valves 512, 514, 530 and 537 and the hand valves 516 and 528 are closed, and the tank valves 524, 538, 532, 536 and 542 are opened to supply (flow) the oxygen-containing gas into the gas supply pipes 520 and 508, the connection pipe 518, the gas supply pipe 526 and the connection pipe 540. After a flow rate of the oxygen-containing gas is adjusted by the MFC 522, the oxygen-containing gas whose flow rate is adjusted is discharged (exhausted) through the exhaust pipe 231 (of the exhauster) via the gas supply pipes 520 and 508, the connection pipe 518, the gas supply pipe 526 and the connection pipe 540. In the present step, switches of the sub-heaters 550a and 550b are turned off so as to stop heating the tank 504 and the secondary piping. Further, in the present step, the liquid source material 502 is not bubbled.

That is, in this step, the tank valve 538 provided on the connection pipe 518 serving as the bypass line is opened to supply the oxygen-containing gas into the secondary piping. That is, the oxygen-containing gas flows (is supplied) through the bypass line connecting the primary piping of the tank 504 and the secondary piping of the tank 504 such that the oxygen-containing gas is supplied without passing through the tank 504, toward the secondary piping through which the vaporized gas has passed (has been supplied). As a result, the passive film is re-formed in the secondary piping through which the vaporized gas has passed. Thereby, it is possible to suppress the corrosion of the piping, particularly in an area where the piping is severely corroded. Therefore, it is possible to reduce the metal contamination caused by the corrosion of the piping. That is, the oxygen-containing gas is not used in the film forming step, but is used to repair (re-form) the passive film of the secondary piping.

Specifically, by flowing (supplying) the oxygen-containing gas into the secondary piping, for example, the oxygen-containing gas reacts with chromium (Cr) constituting the stainless steel. As a result, it is possible to form a chromium oxide film (Cr₂O₃ film) serving as the passive film on an inner surface of the piping, and it is also possible to repair a surface of the stainless steel corroded by the vaporized gas.

As described above, in the present step, when the reactive gas is not supplied to the wafer 200 in the process chamber 201 in the first step, the oxygen-containing gas is exhausted through the exhaust pipe 231 (of the exhauster) connected to the connection pipe 540 such that the oxygen-containing gas is exhausted without passing through the process chamber 201. As a result, regardless of a presence or absence of the wafer 200 in the process chamber 201, by supplying the oxygen-containing gas to the secondary piping, it is possible to form the oxide film on the surface of the secondary piping, and it is also possible to repair (or re-form) the passive film.

As the oxygen-containing gas, for example, a gas such as oxygen (O₂) gas, ozone (O₃) gas, carbon dioxide (CO₂) gas, nitric oxide (NO) gas and nitrous oxide (N₂O) gas may be used. Further, the atmosphere (clean air) may be used as the oxygen-containing gas.

### Inert Gas Atmosphere Step

Subsequently, the tank valves 524 and 542 are closed and the tank valve 512 is opened to supply the inert gas to the secondary piping of the tank 504 through the connection pipe 518 serving as the bypass line. Thereby, an inner atmosphere of the piping is adjusted to an inert gas atmosphere. By filling an inside of the piping with the inert gas in a manner described above, it is possible to secure the safety.

### Inert Gas Removal Step

Subsequently, as shown in FIG. 7B, the tank valve 542 is opened to exhaust the inert gas in the piping to the exhaust pipe 231 (of the exhauster) through the connection pipe 540. By adjusting an inner pressure of the piping of the gas supply assembly 500 to the reduced pressure by the vacuum pump 246, an inside of the piping of the gas supply assembly 500 is vacuum-exhausted. Thereby, it is possible to discharge (exhaust) the oxygen-containing gas used in the purge step from the inside of the piping.

### Performing Predetermined Number of Times

The inert gas atmosphere step and the inert gas removal step (which are described above) are performed at least once. Thereby, it possible to adjust the inner atmosphere of the piping to the inert gas atmosphere.

As described above, by supplying the oxygen-containing gas toward the secondary piping through the bypass line such that the oxygen-containing gas is supplied without passing through the tank 504, the inner surface of the piping is oxidized and passivated so as to form the passive film. Thereby, it is possible to suppress the corrosion of the piping through which the vaporized gas serving as the corrosive gas has passed. As a result, it is possible to suppress the metal contamination caused by the corrosion of the piping.

In addition, it is possible to process the substrate (that is, the wafer 200) while passivating the piping with the oxygen-containing gas. Thereby, it is possible to extend a service life of the piping while improving a processing efficiency.

For example, by using different gases as the carrier gas when supplying the reactive gas and the piping purge gas used for the pipe purging, it is possible to suppress an influence of a gas (which does not contribute to a process) on a quality of the film.

For example, in the piping purge, it is possible to re-form the passive film by using the oxygen-containing gas without heating by the sub-heaters 550a and 550b. As a result, it is possible to obtain an energy saving effect.

It is possible to obtain substantially the same effects described above even when a silicon-containing gas other than the BTCSM gas is used as the source gas, when an oxidizing gas other than the H₂O gas is used as the reactive gas, or when an amine-based gas other than pyridine gas is used as the catalyst gas.

### Second Embodiment of Present Disclosure

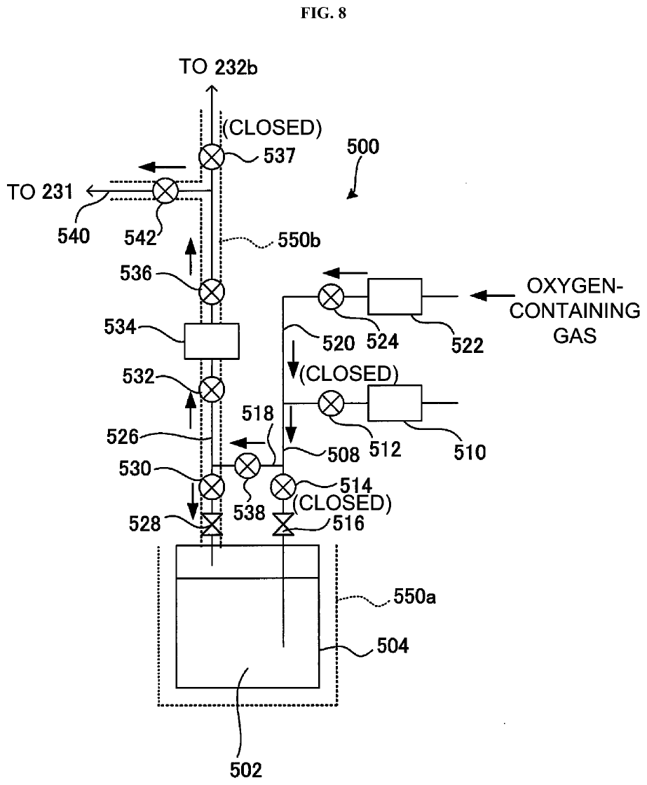

Hereinafter, a second embodiment of the technique of the present disclosure (that is, another example of the purge step in the piping purge) will be described in detail with reference to FIG. 8.

The purge step in the piping purge according to the present embodiment is different from that of the first embodiment described above in that the tank valve 530 and the hand valve 528 (which are valves provided between the tank 504 and the connection portion of the gas supply pipe 526 with the connection pipe 518) are opened. That is, the oxygen-containing gas flows (is supplied) through the bypass line connecting the primary piping of the tank 504 and the secondary piping of the tank 504 such that the oxygen-containing gas is supplied without passing through the tank 504, toward the secondary piping through which the vaporized gas has passed. Thereby, the oxygen-containing gas also flows to a portion (of the gas supply pipe 526) closer to the tank 504 than the connection portion with the connection pipe 518 and a portion (of the gas supply pipe 526) closer to the tank 504 than the tank valve 530.

Specifically, when the tank valve 530 is left open, the gas from the liquid source material 502 in the tank 504 may continuously diffuse toward the secondary piping. Depending on the type of the liquid source material 502, a diffusion of the gas may not be ignored. Therefore, the opening and closing operations of the tank valve 530 and the tank valve 532 are controlled. That is, in the purge step according to the present embodiment, the tank valve 530 is opened and the tank valve 532 is closed such that the oxygen-containing gas can also flow (be supplied) to the portion (of the gas supply pipe 526) closer to the tank 504 than the tank valve 530 using a pressure difference. Then, the tank valve 530 is closed and the tank valve 532 is opened to exhaust the oxygen-containing gas. After repeatedly performing a supply of the oxygen-containing gas and an exhaust of the oxygen-containing gas a plurality of times in a manner described above, the tank valve 530 is closed and the tank valve 532 is opened to complete the purge step according to the present embodiment.

As a result, the oxygen-containing gas is also supplied to the gas supply pipe 526 from a connection portion with the tank 504 to the tank valve 530 (where a rate of corrosion is the highest). Thereby, by forming the passive film inside the piping, it is possible to suppress the corrosion of the piping. Therefore, it is possible to suppress the metal contamination caused by the corrosion of the piping. Further, as described above, the coating film of the fluorine-based resin is formed in the piping between the connection portion of the gas supply pipe 526 with the tank 504 and the tank valve 530. As described above, by coating the piping from the tank 504 to the tank valve 530 (which is particularly prone to the corrosion) with the coating film of the fluorine-based resin, it is possible to further suppress the corrosion of the piping. As a result, it is possible to further reduce the metal contamination caused by the corrosion of the piping. Further, since the substrate can be processed while passivating the piping with the oxygen-containing gas, it is possible to extend the service life of the piping while improving the processing efficiency.

### Third Embodiment of Present Disclosure

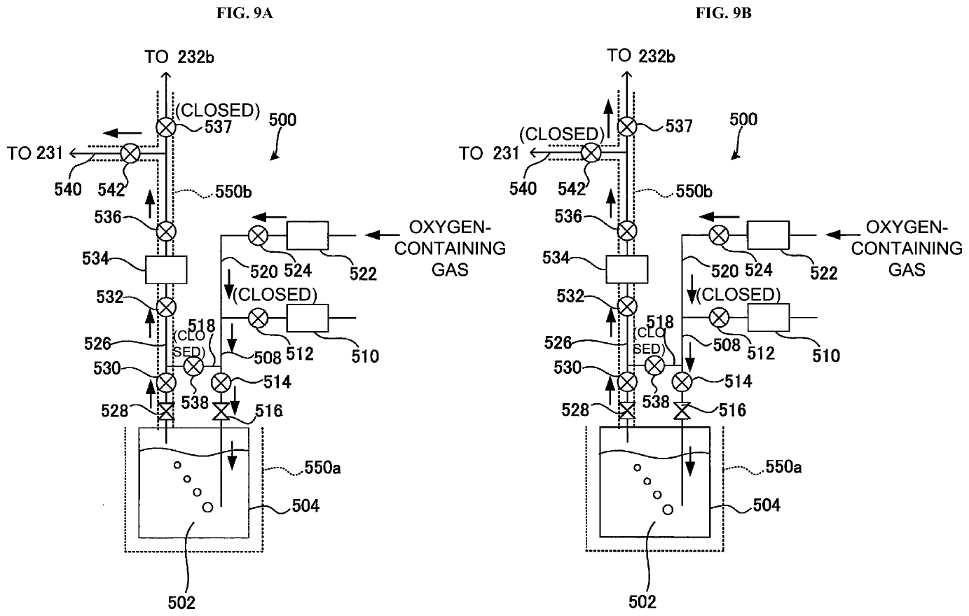

Hereinafter, a third embodiment of the technique of the present disclosure (that is, another example of the piping purge) will be described in detail with reference to FIG. 9A.

The piping purge according to the present embodiment is different from that of the first embodiment described above in that the purge step and the inert gas atmosphere step according to the present embodiment are different from those of the first embodiment described above. That is, the present embodiment is different from the first embodiment in that the purge step and the inert gas atmosphere step according to the present embodiment are performed with the tank valve 538 closed and the tank valves 514 and 530 and the hand valves 516 and 528 open.

According to the present embodiment, as shown in FIG. 9A, the tank valves 512, 538 and 537 are closed, and the tank valves 524 and 514, the hand valves 516 and 528 and the tank valves 530, 532, 536 and 542 are opened to supply (flow) the oxygen-containing gas into the gas supply pipes 520 and 508 and the tank 504. After the flow rate of the oxygen-containing gas is adjusted by the MFC 522, the oxygen-containing gas whose flow rate is adjusted is supplied into the tank 504 through the gas supply pipes 520 and 508, and is discharged (exhausted) through the exhaust pipe 231 (of the exhauster) via the liquid source material 205 in the tank 504 (to which the oxygen-containing gas is supplied) and the gas supply pipes 526 and 540.

That is, in the present step, the purge gas supplier is configured to be capable of introducing the oxygen-containing gas serving as the piping purge gas through the primary piping of the tank 504. More specifically, the purge gas supplier is configured to be capable of supplying the oxygen-containing gas through the secondary piping of the tank 504 via the liquid source material 502 stored in the tank 504. Thereby, it is possible to exhaust the oxygen-containing gas through the exhaust pipe 231 (of the exhauster) connected to the secondary piping of the tank 504 such that the oxygen-containing gas is exhausted without passing through the process chamber 201.

Thereby, it is possible to introduce (supply) the oxygen-containing gas into the tank 504. Further, it is possible to suppress the corrosion of the piping by forming the passive film by oxidizing an inner portion of the tank 504 and the surface of the piping provided adjacent to the tank 504 (which are particularly prone to the corrosion). Therefore, it is possible to reduce the metal contamination caused by the corrosion of the piping. In addition, since the piping can be passivated with the oxygen-containing gas, it is possible to extend the service life of the piping.

### Inert Gas Atmosphere Step

Subsequently, in the inert gas atmosphere step of the present embodiment, the tank valves 524 and 542 are closed and the tank valve 512 is opened to supply the inert gas through the primary piping of the tank 504. Then, the inert gas is supplied through the secondary piping of the tank 504 via the liquid source material 502 stored in the tank 504. Thereby, the inner atmosphere of the piping is adjusted to the inert gas atmosphere. By filling the inside of the piping with the inert gas in a manner described above, it is possible to secure the safety.

### Inert Gas Removal Step

Subsequently, in the inert gas removal step of the present embodiment, the tank valve 542 is opened to exhaust the inert gas in the secondary piping of the tank 504 to the exhaust pipe 231 (of the exhauster) through the connection pipe 540. By adjusting the inner pressure of the piping of the gas supply assembly 500 to the reduced pressure by the vacuum pump 246, the inside of the piping of the gas supply assembly 500 is vacuum-exhausted. Thereby, it is possible to discharge (exhaust) the oxygen-containing gas used in the piping purge from the inside of the piping.

### Performing Predetermined Number of Times

The inert gas atmosphere step and the inert gas removal step (which are described above) of the present embodiment are performed at least once. Thereby, it possible to adjust the inner atmosphere of the piping to the inert gas atmosphere.

### Fourth Embodiment of Present Disclosure

Hereinafter, a fourth embodiment of the technique of the present disclosure (that is, still another example of the purge step in the piping purge) will be described in detail with reference to FIG. 9B.

The purge step in the piping purge according to the present embodiment is different from that of the third embodiment described above in that the tank valve 542 is closed and the tank valve 537 is opened. That is, the oxygen-containing gas is supplied into the tank 504 in the present embodiment similar to the third embodiment. However, the oxygen-containing gas is introduced to the process chamber 201 through the gas supply pipe 232b without being introduced to the exhauster.

That is, in the present embodiment, after the wafer discharging step of the substrate processing described above, the purge step described above is performed in a state where there is no wafer 200 in the process chamber 201. That is, after repeatedly performing the film-forming step a predetermined number of times, the oxygen-containing gas is supplied from the primary piping to the secondary piping to perform the piping purge in the state where there is no wafer 200 in the process chamber 201 described above.

That is, in the present embodiment, the purge gas supplier is configured to be capable of introducing the oxygen-containing gas serving as the piping purge gas through the primary piping. More specifically, the purge gas supplier is configured to be capable of supplying the oxygen-containing gas through the secondary piping via the liquid source material 502 stored in the tank 504. Thereby, it is possible to exhaust the oxygen-containing gas through the exhaust pipe 231 (of the exhauster) via the process chamber 201. That is, it is possible to exhaust the vaporized gas and the purge gas through the secondary piping via the process chamber 201.

Thereby, it is possible to introduce the oxygen-containing gas into the tank 504. Further, it is possible to suppress the corrosion of the piping by forming the passive film by oxidizing the inner portion of the tank 504 and the surface of the piping provided adjacent to the tank 504 (which are particularly prone to the corrosion). Therefore, it is possible to reduce the metal contamination caused by the corrosion of the piping. In addition, since the piping can be passivated with the oxygen-containing gas, it is possible to extend the service life of the piping.

### Other Embodiments of Present Disclosure

While the technique of the present disclosure is described in detail by way of the embodiments and the modified examples described above, the technique of the present disclosure is not limited thereto. The technique of the present disclosure may be modified in various ways without departing from the scope thereof. For example, the embodiments described above are described by way of an example in which the oxygen-containing gas serving as the piping purge gas and the inert gas serving as the carrier gas are supplied to the tank 504 through the same piping. However, a gas for the piping purge gas and a gas for bubbling may be supplied to the tank 504 using separate piping. For example, a piping provided for the gas for bubbling may be inserted into the liquid source material 502, but a piping provided for the gas for the piping purge gas may not be inserted into the liquid source material 502.

For example, the embodiments described above are described by way of an example in which the liquid source material 502 stored in the tank 504 is bubbled and vaporized by introducing the inert gas serving as the carrier gas through the primary piping of the tank 504. However, the technique of the present disclosure is not limited thereto. For example, the oxygen-containing gas may be used as the carrier gas depending on the vaporized gas to be generated. In addition, the inert gas and the oxygen-containing gas may be simultaneously supplied and used as the carrier gas.

For example, the embodiments described above are described by way of an example in which the liquid source material 502 bubbled and vaporized as described above is used as the reactive gas. However, the technique of the present disclosure is not limited thereto. For example, the technique of the present disclosure may be applied when a liquid source material is vaporized and supplied to the process chamber 201.

For example, the embodiments described above are described by way of an example in which a predetermined film is formed on the wafer 200. However, the technique of the present disclosure is not limited thereto. For example, the technique of the present disclosure may be preferably applied when various films such as an oxide film, a nitride film and a metal-containing film are formed on the wafer 200.

For example, the technique of the present disclosure may be preferably applied when the liquid source material is vaporized and used when performing a process such as a CVD (Chemical Vapor Deposition) process, a PVD (Physical Vapor Deposition) process, a process of forming the oxide film, the nitride film or both of the oxide film and the nitride film and a process of forming the metal-containing film. In addition, the technique of the present disclosure may be preferably applied when the liquid source material is vaporized and used when performing a process such as an annealing process, an oxidation process, a nitridation process and a diffusion process.

For example, the embodiment described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at once is used to form the film. For example, the embodiment described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

For example, the embodiments described above are described by way of an example in which a semiconductor manufacturing apparatus for processing a semiconductor wafer is used as the substrate processing apparatus. However, the technique of the present disclosure is not limited thereto. The technique of the present disclosure may also be applied to an LCD (Liquid Crystal Display) manufacturing apparatus for processing a glass substrate.

It is preferable that the recipe (that is, the program containing the information such as the process sequences and the process conditions of the substrate processing) used to for the substrate processing is prepared individually in accordance with the contents of the substrate processing such as a type of the film to be formed, a composition ratio of the film, a quality of the film, a thickness of the film, the process sequences and the process conditions of the substrate processing. That is, a plurality of recipes are prepared. Further, it is preferable that the plurality of recipes are stored in the memory 121c in advance via an electric communication line or the external memory 123. Then, when starting the substrate processing, the CPU 121a preferably selects an appropriate recipe among the recipes stored in the memory 121c of the substrate processing apparatus in accordance with the contents of the substrate processing. Thus, various films of different types, different composition ratios, different qualities and different thicknesses may be universally formed with a high reproducibility using a single substrate processing apparatus. In addition, since a burden on an operator such as inputting the process sequences and the process conditions may be reduced, various processes can be performed quickly while avoiding a malfunction of the apparatus.

The recipe (process recipe) described above is not limited to creating a new recipe. For example, the recipe may be prepared by changing an existing recipe stored in the substrate processing apparatus in advance. When changing the existing recipe to a new recipe, the new recipe may be installed in the substrate processing apparatus via the electric communication line or the recording medium in which the new recipe is stored. Further, the existing recipe already stored in the substrate processing apparatus may be directly changed to the new recipe by operating the input/output device 122 of the substrate processing apparatus.

According to some embodiments of the present disclosure, it is possible to suppress the metal contamination of the substrate due to the corrosion of the piping.

What is claimed is:

1. A method of manufacturing a semiconductor device, comprising:
(a) vaporizing a source material stored in a tank by introducing an inert gas through a primary piping of the tank, and supplying a vaporized gas generated by vaporizing the source material into a process chamber through a secondary piping of the tank; and
(b) supplying an oxygen-containing gas to the secondary piping through which the vaporized gas has passed via a bypass line connecting the primary piping and the secondary side piping such that the oxygen-containing gas is supplied without passing through the tank.

2. The method of claim 1, wherein, in (b), by opening a tank valve provided at the secondary piping between a connection portion of the secondary piping with the bypass line and the tank, the oxygen-containing gas is supplied to a portion of the secondary piping closer to the tank than the tank valve through the tank valve of the secondary piping.

3. The method of claim 1, wherein the secondary piping is provided with a plurality of tank valves, and a coating film of a fluorine-based resin is provided on an inner portion of a piping between a portion of the secondary piping connected to the tank and a tank valve installed closest to the tank among the plurality of tank valves.

4. The method of claim 1, wherein the secondary piping is made of a metal material containing at least chromium (Cr).

5. The method of claim 1, wherein, in (b), the oxygen-containing gas is exhausted through an exhauster connected to the secondary piping such that the oxygen-containing gas is exhausted without passing through the process chamber.

6. The method of claim 1, wherein (b) is performed in a state where there is no substrate in the process chamber.

7. The method of claim 1, further comprising
(c) adjusting an inner atmosphere of the secondary piping to an inert gas atmosphere by supplying the inert gas to the secondary piping through the bypass line.

8. The method of claim 7, further comprising
(d) adjusting an inner pressure of the secondary piping to a reduced pressure by vacuum-exhausting the inert gas in the secondary piping,
wherein (c) and (d) are performed at least once to adjust the inner atmosphere of the secondary piping to the inert gas atmosphere.

9. The method of claim 3, wherein the fluorine-based resin is at least one resin selected from the group consisting of polytetrafluoroethylene, perfluoroalkoxy alkane, ethylene-tetrafluoroethylene copolymer, perfluoroethylene-propene copolymer, polyvinylidene fluoride, polychlorotrifluoroethylene and ethylene-chlorotrifluoroethylene copolymer.

10. The method of claim 1, wherein the oxygen-containing gas is at least one gas selected from the group of oxygen gas, ozone gas, carbon dioxide gas, nitric oxide gas and nitrous oxide gas.

11. The method of claim 1, wherein the atmosphere serves as the oxygen-containing gas.

12. The method of claim 1, wherein (b) is performed after (a) is performed a predetermined number of times.

13. The method of claim 1, wherein (a) and (b) are performed alternately a plurality of times.

14. The method of claim 13, wherein (b) is performed after (a).

15. A gas supply method comprising:
supplying an oxygen-containing gas to a secondary piping of a tank through which a vaporized gas has passed via a bypass line connecting a primary piping of the tank and the secondary piping of the tank such that the oxygen-containing gas is supplied without passing through the tank.

16. The gas supply method of claim 15, further comprising
adjusting an inner atmosphere of the secondary piping to an inert gas atmosphere by supplying an inert gas to the secondary piping through the bypass line.

17. A substrate processing apparatus comprising:
a process chamber in which a substrate is processed;
a process gas supplier configured to be capable of vaporizing a source material stored in a tank by introducing an inert gas through a primary piping of the tank and capable of supplying a vaporized gas generated by vaporizing the source material to the process chamber through a secondary piping of the tank; and
a purge gas supplier configured to be capable of supplying an oxygen-containing gas to the secondary piping through which the vaporized gas has passed via a bypass line connecting the primary piping and the secondary piping such that the oxygen-containing gas is supplied without passing through the tank.

18. The substrate processing apparatus of claim 17, further comprising
an exhauster configured to be capable of exhausting the vaporized gas and the oxygen-containing gas through the secondary piping such that the vaporized gas and the oxygen-containing gas are exhausted without passing through the process chamber.

19. A non-transitory computer-readable recording medium storing a program that causes a substrate processing apparatus, by a computer, to perform a process comprising the gas supply method of claim 15.
